(19) United States
(12) Patent Application Publication
(10) Pub. No.: US 2003/0016574 A1
(43) Pub. Date: Jan. 23, 2003

(54) Method of adjusting semiconductor buffer capability of semiconductor device, electronic system, and semiconductor device

(76) Inventor: Shogo Hachiya, Ome-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/187,846

(22) Filed: Jul. 3, 2002

(30) Foreign Application Priority Data
Jul. 5, 2001 (JP) 2001-205150

(51) Int. Cl. G11C 29/00

(52) U.S. Cl. 365/200

(57) ABSTRACT

In a memory module, there is provided a ROM which stores characteristic variation information representing variations in the characteristics of each semiconductor memory in values or the like. The characteristic variation information is, for example, the data measured in the manufacturing stages of a semiconductor device. The BIOS, when being started up, reads out the characteristic variation information stored in the ROM, determines the optimum value for the buffer capability of each semiconductor memory on the basis of the characteristic variation information, and sets the memory controller via a local bus in order to suitably adjust the buffer capability of each semiconductor memory. The memory controller supplies to the memory module a signal with such a signal magnitude as makes the buffer capability of each semiconductor memory suitably in accordance with the contents set by the BIOS.

### CROSS-REFERENCE TO RELATED APPLICATIONS

This application is based upon and claims the benefit of priority from the prior Japanese Patent Application No. 2001-205150, filed Jul. 5, 2001, the entire contents of which are incorporated herein by reference.

### BACKGROUND OF THE INVENTION

1. Field of the Invention

The present invention relates to a method of adjusting a buffer capability of a semiconductor device, an electronic system, and a semiconductor device.

2. Description of the Related Art

In recent years, various semiconductor devices have been developed and manufactured in accordance with applications. There are various types of semiconductor devices, including a single semiconductor memory connected to a memory controller and a semiconductor module formed by providing a plurality of semiconductor memories of this type on a substrate.

Semiconductor devices must be designed and manufactured so as to have a suitable buffer capability to guarantee a signal having a more stable quality than a specific level.

For example, when the applied load is too heavy, the parasitic input capacitance increases, which dulls the rising of the waveform of the input signal to the semiconductor. Therefore, it is necessary to increase the buffer capability. On the other hand, when the applied load is too light, the parasitic input capacitance decreases, which permits the rising of the waveform of the input signal to the semiconductor to overshoot. Therefore, it is necessary to decrease the buffer capability. Taking these things into account, semiconductor devices are designed and manufactured so that their buffer capabilities have suitable values in accordance with the loads on the circuits to be connected to the input side.

As described above, the buffer capability of the semiconductor device should be neither too high nor too low and must be set suitably in accordance with the load.

However, actually manufactured semiconductor devices vary in their electrical characteristics, depending on the design method, manufacturing method, environment of use, and other factors. For example, the deviation of the dimensions (e.g., thickness) of a semiconductor or an insulator from the proper values in the manufacturing processes (e.g., etching or evaporation) causes variations in the characteristics.

Variations in the characteristics include variations in the input capacitance of the semiconductor and variations in the characteristic of the clamp diode in the semiconductor. Moreover, there are also variations in the impedance of the printed-circuit board that transmits signals from a semiconductor.

When variations in these characteristics have exceeded specific limits, the buffer capability of the semiconductor device fluctuates, with the result that the quality of the signal waveform deteriorates. This contributes to erroneous operation of the semiconductor device or the breakdown of its elements.

### BRIEF SUMMARY OF THE INVENTION

Accordingly, it is an object of the present invention to provide a semiconductor buffer capability adjusting method, an electronic system, and a semiconductor device which are capable of improving the quality of a signal waveform by suitably setting the buffer capability of the semiconductor device.

According to an aspect of the present invention, there is provided a semiconductor device, comprising a memory configured to store characteristic information indicating a buffer capability of the semiconductor device; and a terminal from which the characteristic information stored in the memory is capable of being read out.

According to another aspect of the present invention, there is provided a semiconductor device, comprising a memory configured to store attribute information indicating least one of a manufacturer, a factory, a lot, and a manufacturing process of the semiconductor device; and a terminal from which the attribute information stored in the memory is capable of being read out, the read-out attribute information being usable to adjust a buffer capability of the semiconductor device.

According to still another aspect of the present invention, there is provided an electronic system, comprising a semiconductor device including a memory configured to store characteristic information indicating electrical characteristics inherent to the semiconductor device; means for reading out the characteristic information from the memory; and means for adjusting a capability of a buffer of the semiconductor device using the read-out characteristic information.

According to still another aspect of the present invention, there is provided an electronic system, comprising a semiconductor device; a temperature sensor configured to sense a temperature of the semiconductor device; and an adjusting unit configured to adjust a buffer capability of the semiconductor device on the basis of the temperature sensed by the temperature sensor.

According to still another aspect of the present invention, there is provided a method of adjusting a buffer capability of a semiconductor device, the method comprising storing characteristic information indicating electrical characteristics inherent to the semiconductor device into the semiconductor device beforehand; reading out the characteristic information from the semiconductor device; and adjusting the buffer capability of the semiconductor device using the readout characteristic information.

According to still another aspect of the present invention, there is provided a method of adjusting a buffer capability of a semiconductor device, the method comprising reading out characteristic information from the semiconductor device, the characteristic information indicating electrical characteristics inherent to the semiconductor device; and adjusting the buffer capability of the semiconductor device using the read-out characteristic information.

According to still another aspect of the present invention, there is provided a method of adjusting a buffer capability of a semiconductor device, the method comprising sensing a temperature of the semiconductor device by a temperature sensor; and adjusting the buffer capability of the semiconductor device on the basis of the temperature sensed by the temperature sensor.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 shows the configuration of an electronic system according to an embodiment of the present invention;

FIG. 2 shows a modification of the system shown in FIG. 1;

FIG. 3 shows a modification of the system shown in FIG. 2;

FIGS. 4A to 4C are diagrams to help explain waveforms of the input signal to a semiconductor;

FIG. 5 is a drawing to help explain approaches, by classification, of acquiring information about variations in the characteristics of semiconductor devices;

FIG. 6 shows an example of the configuration of a buffer capability adjusting circuit provided in the memory controller of the system in FIG. 1;

FIG. 7 is a flowchart to help explain the operation of the system in FIG. 1; and

FIG. 8 is a flowchart to help explain the operation of the system in FIG. 3.

### DETAILED DESCRIPTION OF THE INVENTION

Hereinafter, referring to the accompanying drawings, embodiments of the present invention will be explained.

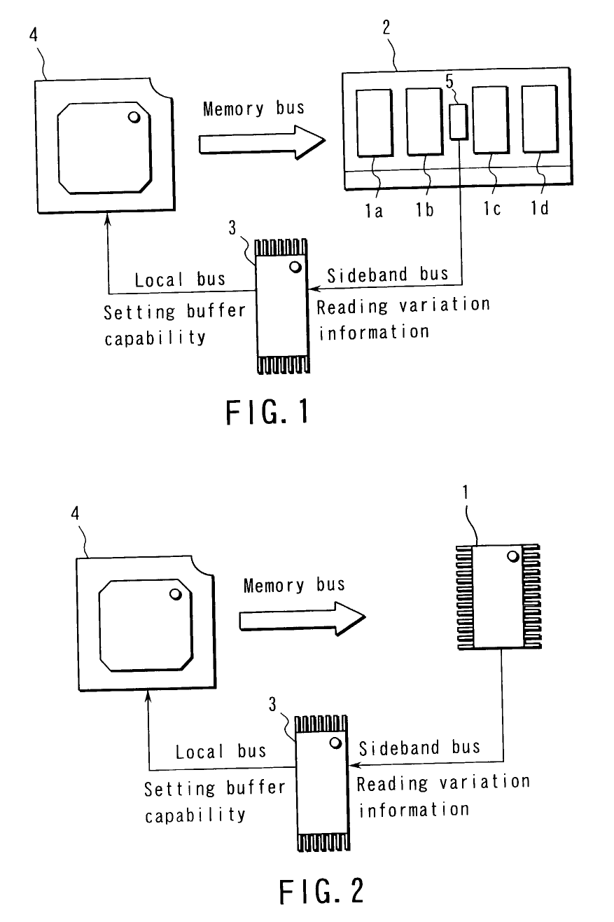

FIG. 1 shows the configuration of an electronic system according to an embodiment of the present invention. In the system of FIG. 1, a plurality of semiconductor memories provided in a memory module are to be adjusted in buffer capability. This system is realized in the form of an electronic apparatus, such as a personal computer or a mobile information terminal.

This system includes a memory module 2 in which a plurality of semiconductor memories (e.g., DRAMs) 1a to 1d are provided, a BIOS (Basic Input/Output System) 3 that effects settings related mainly to the hardware configuration, and a memory controller 4 that controls the data input/output of the memory module 2 via a memory bus.

In each semiconductor memory in the memory module 2, various factors in the memory's design stage and manufacturing stage have created variations in the electrical characteristics (e.g., variations in the input capacitance of the semiconductor device, variations in the characteristics of the clamp diode in the semiconductor device, or variations in the impedance of the printed-circuit board that transmits signals from the semiconductor device). Such variations degrade the quality of the waveform of the input signal to each semiconductor memory. For example, it is assumed that, of the input signal waveforms (of three types) shown in FIGS. 4A to 4C, FIG. 4A shows a desirable waveform. In FIG. 4B, the rising of the input signal waveform overshoots, with the result that the buffer capability becomes too high. In FIG. 4C, the rising of the input signal waveform becomes dull, with the result that the buffer capability becomes too low.

Taking these into account, a ROM 5 is provided in the memory module 2 in the embodiment. The ROM 5 stores characteristic information indicating a buffer capability of the semiconductor device or indicating electrical characteristic inherent to the semiconductor device. The characteristic information involves characteristic variation information which expresses variations in the characteristics of each semiconductor memory in numbers. (Variations in the characteristics include variations in the input capacitance of the semiconductor device, variations in the characteristics of the clamp diode in the semiconductor device, and variations in the impedance of the printed-circuit board that transmits signals from the semiconductor device.) Thus, by referring to the characteristic variation information stored in the ROM 5, it is possible to adjust the buffer capability of the semiconductor device and obtain a suitable quality of the signal. The characteristic variation information, which is the data measured in the manufacturing stage of the semiconductor device, is stored in the ROM 5 before shipment of the product.

Instead of the characteristic variation information being stored in the ROM 5, characteristic information representing the previously measured slew rate, drive capability, voltage amplitude, and current characteristic of each semiconductor memory may be stored. From such characteristic information, too, it is possible to grasp variations in the characteristics and determine the optimum value for the buffer capability.

The characteristics of semiconductor devices vary, depending on manufacturer, factory, lot, manufacturing process, and other factors. They also vary, according to differences in the environment, equipment, and conditions at the time of manufacturing. When the manufacturer, lot, and manufacturing process are the same, the tendency of variations is the same. Therefore, these items of attribute information may be stored in the ROM 5 in place of the characteristic variation information.

Furthermore, the characteristic variation information, characteristic information, and attribute information may be stored simultaneously in the ROM 5.

The BIOS 3, when being started up, carries out the setting process mainly related to the hardware configuration. At that time, the BIOS 3 reads out the characteristic variation information stored in the ROM 5 through a sideband bus and a terminal. On the basis of the characteristic variation information, the BIOS 3 determines the optimum value for the buffer capability of each semiconductor memory and sets the memory controller 4 via a local bus in order to suitably adjust the buffer capability of each of the semiconductor memories 1a to 1d.

For example, in the case of a semiconductor memory whose buffer capability is too high because the rising of the input signal waveform has overshot as shown in FIG. 4B, the BIOS 3 performs a setting process to decrease the buffer capability. On the other hand, in the case of a semiconductor memory whose buffer capability is too low because the rising of the input signal waveform has dulled as shown in FIG. 4C, the BIOS 3 performs a setting process to increase the buffer capability.

The processes carried out by the BIOS 3 may be performed by an application program managed under the operating system.

The memory controller 4 supplies to the memory module 2 (each semiconductor memory) a signal of such a magnitude as makes the buffer capability of each semiconductor memory suitable in accordance with the contents set by the BIOS 3.

For example, when the BIOS 3 has carried out the setting process to decrease the buffer capability, the memory controller 4 lowers the magnitude of the signal supplied to the corresponding semiconductor memory. On the other hand, when the BIOS 3 has carried out the setting process to increase the buffer capability, the memory controller 4 raises the magnitude of the signal supplied to the corresponding semiconductor memory.

FIG. 2 shows a modification of the system shown in FIG. 1. In FIG. 2, the same parts as those in FIG. 1 are indicated by the same reference numerals and a concrete explanation of them will be omitted.

While in the system of FIG. 1, the semiconductor memories 1a to 1d provided in the memory module are to be adjusted in buffer capability, a single memory module 1 is to be adjusted in buffer capability in the system of FIG. 2.

Furthermore, while in the system of FIG. 1, characteristic variation information about each semiconductor memory has been stored in the ROM 5, characteristic variation information about the semiconductor memory 1 is stored in the semiconductor memory 1 itself in the system of FIG. 2. That is, the semiconductor memory 1 has a storage section for storing the characteristic variation information. The characteristic variation information is the data previously measured in the manufacturing stage and stored in the storage section before shipment of the product.

Instead of the characteristic variation information, characteristic information representing the previously measured slew rate, drive capability, voltage amplitude, current characteristic, and other characteristics of each semiconductor memory may be stored in the storage section. Moreover, attribute information representing the manufacturer, factory, lot, manufacturing process, and other attributes may be stored. In addition, the characteristic variation information, characteristic information, and attribute information may be stored simultaneously in the storage section.

The BIOS 3, when being started up, reads out the characteristic variation information from the storage section in the semiconductor memory 1 via the sideband bus and a terminal. On the basis of the characteristic variation information, the BIOS 3 determines the optimum value for the buffer capability of the semiconductor memory 1 and sets the memory controller 4 via a local bus in order to suitably adjust the buffer capability of the semiconductor memory 1.

The memory controller 4 supplies to the semiconductor memory 1 a signal of such a magnitude as makes the buffer capability of the semiconductor memory 1 suitable in accordance with the contents set by the BIOS 3.

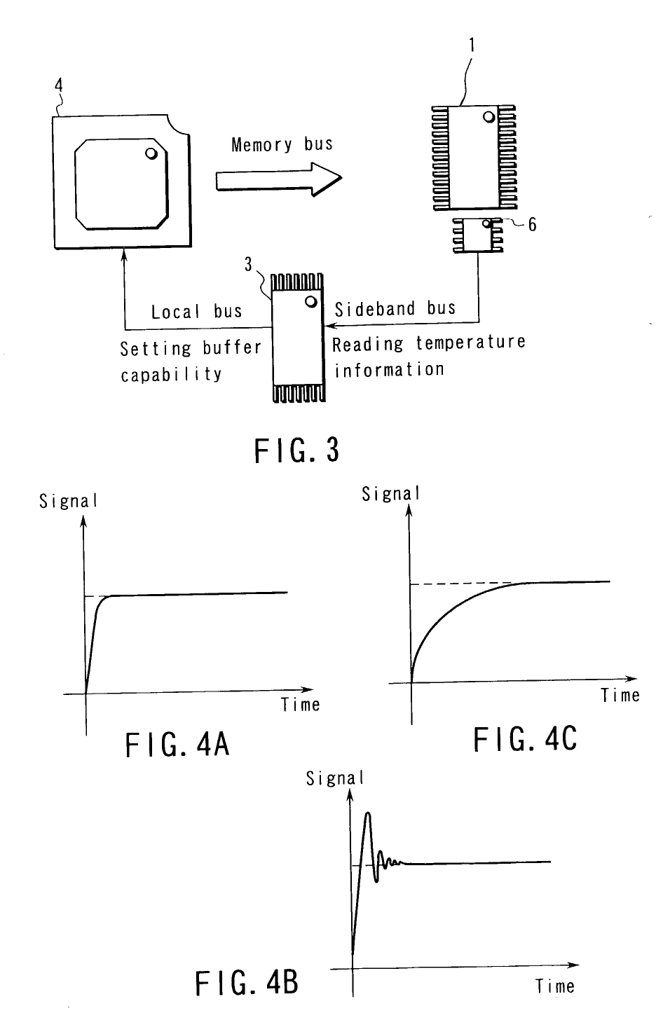

FIG. 3 shows a modification of the system shown in FIG. 2. In FIG. 3, the same parts as those in FIG. 2 are indicated by the same reference numerals and a concrete explanation of them will be omitted.

While in the system of FIG. 2, the optimum value for the buffer capability has been determined on the basis of the characteristic variation information stored in the storage section of the semiconductor memory 1, the system of FIG. 3 is such that a temperature sensor 6 for sensing the temperature of the semiconductor memory 1 is provided near the semiconductor memory 1 and the optimum value for the buffer capability is determined on the basis of the temperature information obtained from the temperature sensor 6.

The characteristics of the semiconductor vary, depending not only on manufacturing processes but also variations in the temperature. The reason is that, when electrons pass through a conductor, the higher the temperature, the higher the series resistance. Therefore, in the system of FIG. 3, the optimum value for the buffer capability is determined on the basis of the temperature information.

The BIOS 3, when being started up, reads out information about the temperature of the semiconductor memory 1 from the temperature sensor. On the basis of the temperature information, the BIOS 3 determines the optimum value for the buffer capability of the semiconductor memory 1 and sets the memory controller 4 via a local bus in order to adjust the buffer capability of the semiconductor memory 1.

The memory controller 4 supplies to the semiconductor memory 1 a signal of such a magnitude as makes the buffer capability of the semiconductor memory 1 suitable in accordance with the contents set by the BIOS 3.

The configuration of FIG. 2 may be combined with the configuration of FIG. 3 to determine the optimum value for the buffer capability on the basis of the characteristic variation information and the temperature information.

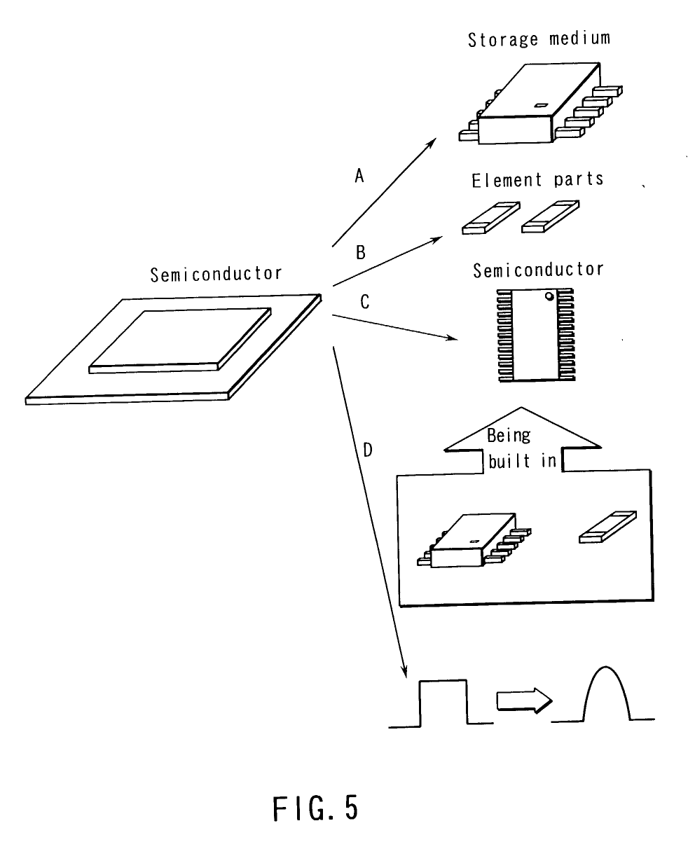

FIG. 5 is a drawing to help explain approaches, by classification, of acquiring information about variations in the characteristics of semiconductor devices.

The letter A indicates an approach of storing characteristic variation information about semiconductor devices into a specific storage medium (e.g., a magnetic storage unit) beforehand and reading out the characteristic variation information from the medium as the need arises. In this case, the storage medium may be of any type, as long as the information can be stored into and read from the medium.

The letter B indicates an approach of holding characteristic variation information about semiconductor devices in advance with specific element parts and reading out the characteristic variation information as the need arises. For example, the characteristic variation information may be expressed by digital data made up of a combination of high and low levels of a signal with resistances and fuses. Alternatively, setting the coefficients of passive elements to specific values enables the characteristic variation information to be expressed. In this case, element parts may be of any type, as long as they can store the information and be read from.

The letter C indicates an approach of holding characteristic variation information about a semiconductor device in the semiconductor device itself and reading out the characteristic variation information as the need arises. In the semiconductor device, for example, the storage medium and element parts used in the approaches indicated by A and B may be incorporated. Since the semiconductor manufacturing processes are carried out on wafers, the tendency of variations is the same for the same wafer or die. Therefore, passive parts are formed in a semiconductor and their values are checked, which enables variations in the characteristics of the semiconductor device itself to be determined.

The letter D indicates an approach of obtaining characteristic variation information by actually operating a semiconductor device and measuring the waveform. For example, variations in semiconductor devices can be determined by driving the buffer and measuring the reflected wave coming back to the buffer by known TDR (Time Domain Reflectometry) techniques. Furthermore, examining the borderline between success and failure in data transmission while changing the output timing of the buffer enables variations in semiconductor devices to be determined.

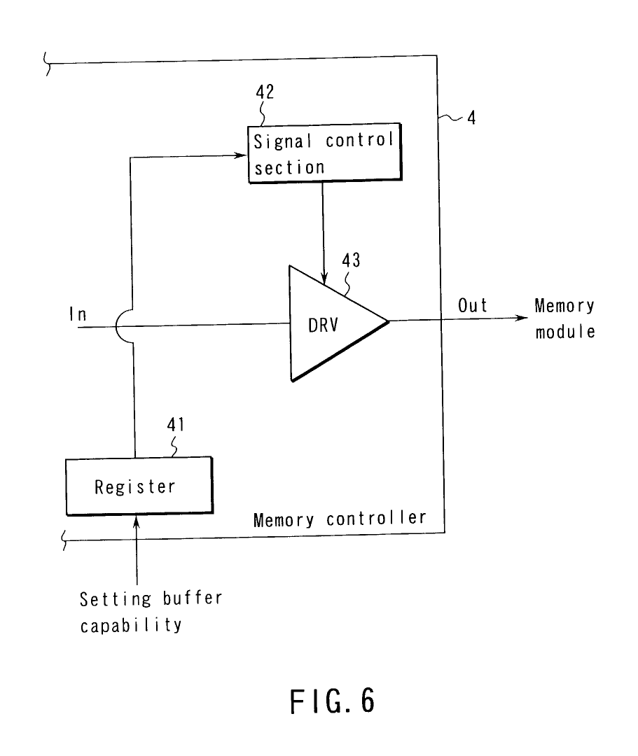

FIG. 6 shows an example of the configuration of a buffer capability adjusting circuit provided in the memory controller 4 of the system in FIG. 1. Although only the configuration of the circuit corresponding to one semiconductor memory is shown in FIG. 6 to simplify an explanation, as many adjusting circuits as the number of semiconductor memories to be adjusted are actually provided.

In the memory controller 4, there are provided a register 41, a signal controller 42, a driver 43, and other components.

The register 41 is for setting buffer capability adjusting data for adjusting the buffer capability of the semiconductor device. The setting of the register 41 is effected by software, such as the BIOS 3.

The signal control section 42 controls the signal output of the driver 43 in accordance with the value set in the register 41.

The driver 43, which is controlled by the signal control section 42, changes the magnitude of a signal to be supplied to the semiconductor device.

The above circuit configuration may be applied to the memory controller 4 in the systems of FIG. 2 and FIG. 3.

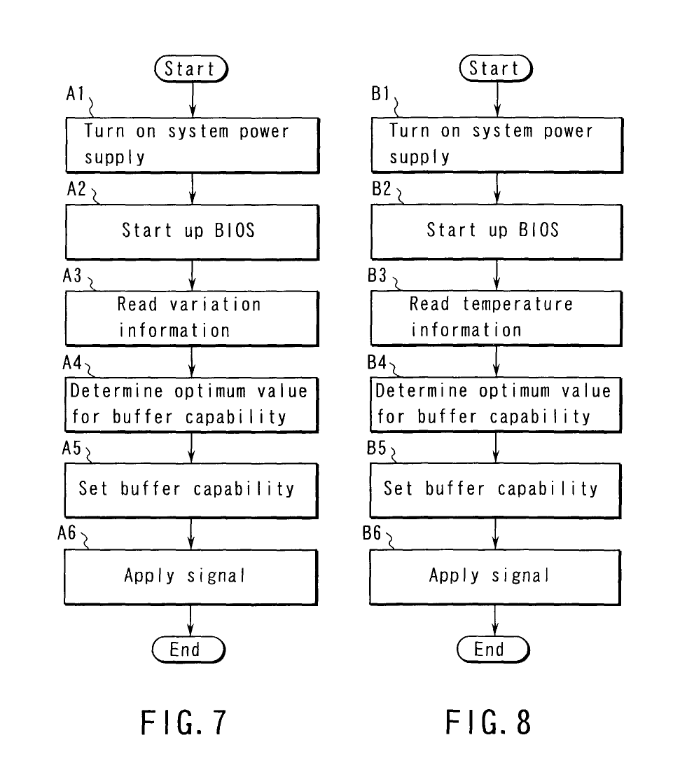

Next, referring to FIG. 7, the operation of the system in FIG. 1 will be explained.

After the power supply of the system is turned on (step A1), the BIOS 3 is started (step A2). As a result, the setting process of the hardware in the system is carried out. At that time, the characteristic variation information stored in the ROM 5 of the memory module 2 is read out by the BIOS 3 (step A3).

Then, the BIOS 3 determines the optimum value for the buffer capability of each semiconductor memory on the basis of the read-out characteristic variation information (step A4) and sets the memory controller 4 to suitably adjust the buffer capability of each of the semiconductor memories 1a to 1d (step A5).

After the memory controller 4 has been set, the memory controller 4 supplies to the semiconductor memory 1 a signal of such a magnitude as makes the buffer capability of the semiconductor memory 1 suitable in accordance with the setting (step A6).

The optimum value of the buffer capability determined in step A4 may be stored in a specific storage section. When the system is started up next time, the memory controller 4 may be set using the stored optimum value without reading out the data from the ROM 5.

The operation of the system in FIG. 2 is the same as that of the system in FIG. 1 except that the buffer capability of only the semiconductor memory 1 is to be adjusted and that, since the characteristic variation information is stored in the storage section of the semiconductor memory 1, it is read out from the storage section.

Next, referring to FIG. 8, the operation of the system in FIG. 3 will be explained.

After the power supply of the system is turned on (step B1), the BIOS 3 is started (step B2). As a result, the setting process of the hardware in the system is carried out. At that time, temperature information is read out by the BIOS 3 from the temperature sensor that senses the temperature of the semiconductor memory 1 (step B3).

Then, the BIOS 3 determines the optimum value for the buffer capability of each semiconductor memory on the basis of the read-out temperature information (step B4) and sets the memory controller 4 to suitably adjust the buffer capability of each of the semiconductor memories 1a to 1d (step B5).

After the memory controller 4 has been set, the memory controller 4 supplies to the semiconductor memory 1 a signal of such a magnitude as makes the buffer capability of the semiconductor memory suitable in accordance with the setting (step B6).

As described above, with the embodiment, characteristic variation information, characteristic information, or attribute information about semiconductor devices, such as memory modules or semiconductor memories, is held in a specific place beforehand and the information is referred to when the semiconductor devices are used. This makes it possible to suitably set the buffer capability of the semiconductor devices. Furthermore, characteristic variation information is obtained by actually operating a semiconductor device and measuring the waveform. This makes it possible to suitably set the buffer capability of the semiconductor device. Moreover, use of temperature information about a semiconductor device enables the buffer capability of the semiconductor device to be set suitable. This enables the semiconductor device to assure a suitable signal quality, which prevents the semiconductor device from operating erroneously or having its elements damaged.

As described above in detail, with the present invention, it is possible to suitably set the buffer capability of a semiconductor device and improve the quality of its signal waveform.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a memory configured to store characteristic information indicating a buffer capability of the semiconductor device; and
a terminal from which the characteristic information stored in the memory is capable of being read out.

2. The semiconductor device according to claim 1, wherein the characteristic information stored in the memory corresponds to data that has been measured in a manufacturing stage of the semiconductor device.

3. The semiconductor device according to claim 1, wherein the characteristic information stored in the memory indicates at least one of a slew rate, a drive capability, a voltage amplitude, and a current characteristic of the semiconductor device.

4. A semiconductor device, comprising:
a memory configured to store attribute information indicating least one of a manufacturer, a factory, a lot, and a manufacturing process of the semiconductor device; and
a terminal from which the attribute information stored in the memory is capable of being read out, the read-out attribute information being usable to adjust a buffer capability of the semiconductor device.

5. An electronic system, comprising:
a semiconductor device including a memory configured to store characteristic information indicating electrical characteristics inherent to the semiconductor device;
means for reading out the characteristic information from the memory; and
means for adjusting a capability of a buffer of the semiconductor device using the read-out characteristic information.

6. An electronic system, comprising:
a semiconductor device;
a temperature sensor configured to sense a temperature of the semiconductor device; and
an adjusting unit configured to adjust a buffer capability of the semiconductor device on the basis of the temperature sensed by the temperature sensor.

7. A method of adjusting a buffer capability of a semiconductor device, said method comprising:
storing characteristic information indicating electrical characteristics inherent to the semiconductor device into the semiconductor device beforehand;
reading out the characteristic information from the semiconductor device; and
adjusting the buffer capability of the semiconductor device using the read-out characteristic information.

8. The method according to claim 7, wherein the stored characteristic information corresponds to data that has been measured in a manufacturing stage of the semiconductor device.

9. The method according to claim 7, wherein the stored characteristic information indicates at least one of a slew rate, a drive capability, a voltage amplitude, and a current characteristic of the semiconductor device.

10. A method of adjusting a buffer capability of a semiconductor device, said method comprising:
reading out characteristic information from the semiconductor device, the characteristic information indicating electrical characteristics inherent to the semiconductor device; and
adjusting the buffer capability of the semiconductor device using the read-out characteristic information.

11. A method of adjusting a buffer capability of a semiconductor device, said method comprising:
sensing a temperature of the semiconductor device by a temperature sensor; and
adjusting the buffer capability of the semiconductor device on the basis of the temperature sensed by the temperature sensor.
